(19) United States
(12) Patent Application Publication
(10) Pub. No.: US 2011/0181157 A1
(43) Pub. Date: Jul. 28, 2011

(54) Modularized server housing

(76) Inventor: Ho-Min Lin, Lu Chu Hsiang (TW)

(21) Appl. No.: 11/902,178

(22) Filed: Sep. 19, 2007

(51) Int. Cl. H05K 5/02

(52) U.S. Cl. 312/107

(57) ABSTRACT

A modularized server housing that improves maintenance efficiency is disclosed to include a first bracket, which has two sliding rails at two sides, a second bracket, which has two opposite upright side panels for guiding the sliding rails into the inside of the second bracket and a retaining rod at each upright side panel near the front side, and two movable fasteners respectively provided at the first bracket for fastening to the retaining rods of the upright side panels to lock the first bracket to the second bracket.

### BACKGROUND OF THE INVENTION

1. Field of the Invention

The present invention relates to a server housing and more particularly, to a modularized server housing, which has movable fasteners provided at a first bracket for fastening to respective retaining rods at a second bracket to improve maintenance efficiency and carrying convenience.

2. Description of the Related Art

In recent decades, electronic products are well developed to bring great convenience to people. Early designs of electronic products have a simple function and a large size. Modern electronic products have light, thin, small and short characteristics with a strong power.

A conventional electronic apparatus has the central processing unit (computing unit and control unit) and the memory integrated in a housing for processing and storing data. However, due to the reasons of frequent change or updating of storage data, population of network application, and big amount of processing data, the memory unit may have to be expanded, changed, or carried to another place. A conventional computer or server housing cannot achieve this function to satisfy the requirements.

There are computers and servers that allow use of mobile memory devices. However, the central processing unit of a server is not conveniently replaceable. When the central processing unit is damaged, the data in the memory devices become not accessible, and the whole system cannot be run, resulting in a big loss.

Therefore, it is desirable to find a way that overcomes electronic device replacement problem, improving maintenance efficiency and carrying convenience.

### SUMMARY OF THE INVENTION

The present invention has been accomplished under the circumstances in view. It is the main object of the present invention to provide a server housing, which is modularized to improve maintenance efficiency and carrying convenience.

To achieve this and other objects of the present invention, the modularized server housing comprises a first bracket, the first bracket comprising two sliding rails disposed at two opposite lateral sides thereof; a second bracket for receiving the first bracket, the second bracket comprising two upright side panels disposed at two opposite lateral sides thereof for guiding the sliding rails into the inside of the second bracket, the upright side panels each having a retaining rod disposed near a front side of the second bracket; and a plurality of movable fasteners respectively provided at the first bracket for fastening to the retaining rods of the upright side panels to lock the first bracket to the second bracket.

By means of the technical measure of providing movable fasteners at the first bracket for fastening to respective retaining rods at the second bracket, the invention achieve the advantages of improving maintenance efficiency and carrying convenience.

### BRIEF DESCRIPTION OF THE DRAWINGS

FIG. 1 is a top plain view of a present invention, showing processors and data storage devices respectively mounted in the first bracket and the second bracket.

FIG. 2 is an oblique top elevation of a part of the present invention, showing a separated status of the first bracket and the second bracket.

FIG. 3 corresponds to FIG. 2 when viewed from another angle.

FIG. 4 is an enlarged view of a part of the present invention, showing the positioning of one movable fastener in the first bracket.

FIG. 5 is an enlarged view of a part of the present invention, showing the movable fastener provided at the first bracket and fastened to the second bracket.

FIG. 6 corresponds to FIG. 5 when viewed from another angle.

FIG. 7 is an exploded view of a part of the present invention, showing the structure of the movable fastener.

FIG. 8 is a schematic drawing showing of the first bracket in the second bracket.

### DETAILED DESCRIPTION OF THE PREFERRED EMBODIMENT

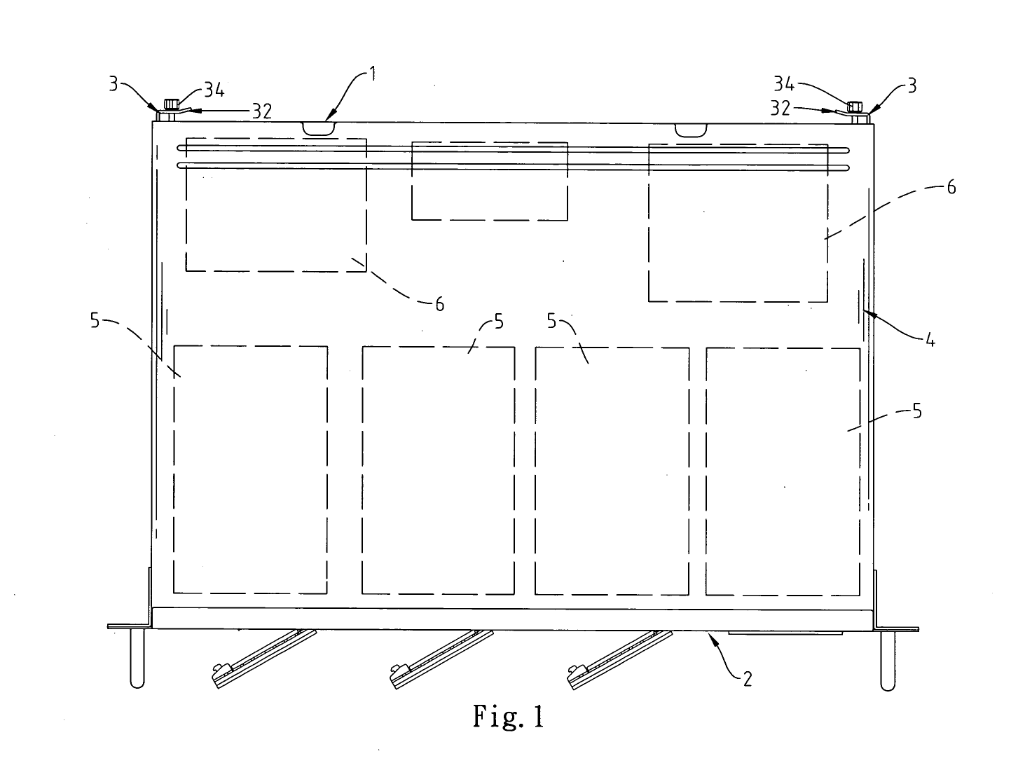

Referring to FIGS. 1-3, a modularized server housing in accordance with the present invention is shown comprised of a first bracket 1, a second bracket 2, a plurality of movable fasteners 3, and a cover plate 4.

Before description of the preferred embodiment of the present invention, it is to be understood that like reference signs indicate light parts through out the drawbacks.

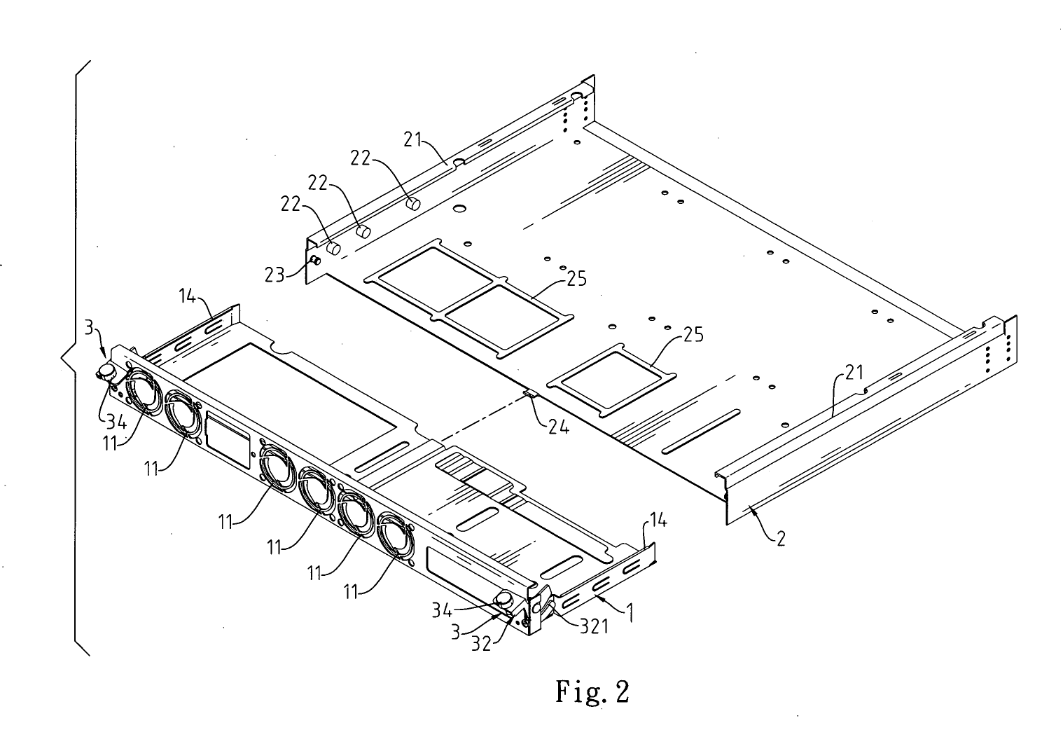

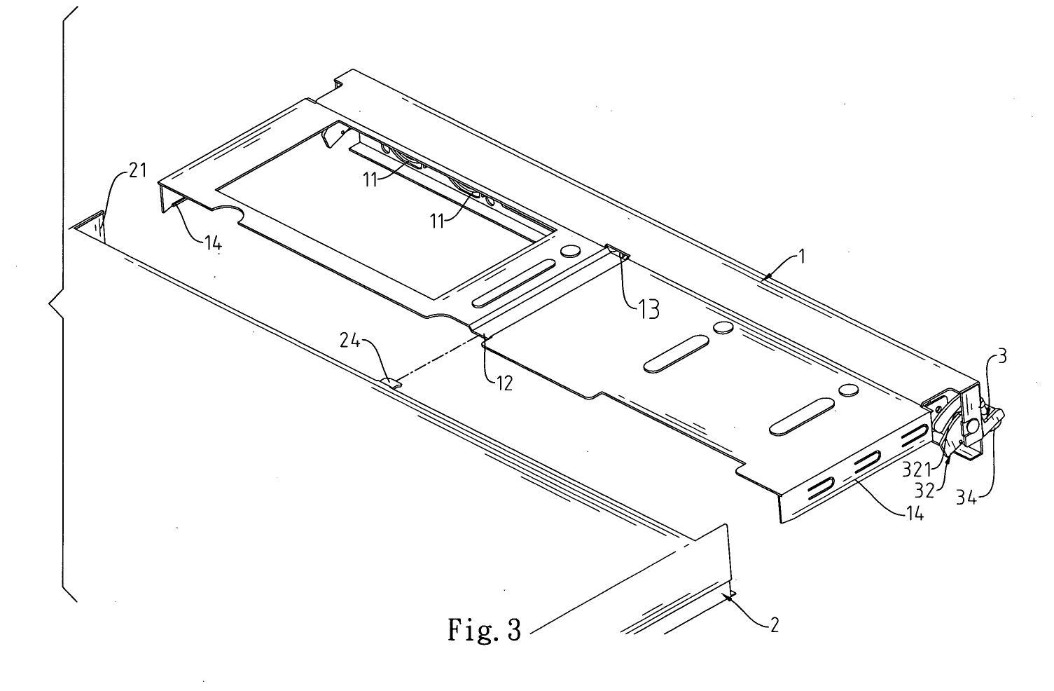

Referring to FIGS. 2 and 3 again, the first bracket 1 is an angled plate member having a plurality of fan holes 11 on its upright front wall, a sliding groove 12 on its horizontal bottom wall, a through hole 13 disposed at one end of the sliding groove 12, and sliding rails 14 arranged in parallel at two opposite lateral sides relative to the sliding groove 12.

Referring to FIGS. 2 and 3 again, the second bracket 2 is slidably coupled to the first bracket 1, comprising two upright side panels 21 for guiding movement of the sliding rails 14 of the first bracket 1 relative to the second bracket 2. Each upright side panel 21 has a plurality of guide pins 22 and a retaining rod 23 disposed at an inner side. The retaining rod 23 is disposed near the outer end of the respective upright side panel 21. The guide pins 22 are adapted to guide movement of the sliding rails 14 of the first bracket 1 in between the two opposite side panels 21 of the second bracket 2 in course. The second bracket 2 further comprises a retaining member 24 forwardly protruding from a front side thereof and movable along the sliding groove 12 for engaging into the through hole 13 to hold the first bracket in position, and a plurality of reinforcing ribs 25 protruded from the bottom surface to reinforce the structural strength.

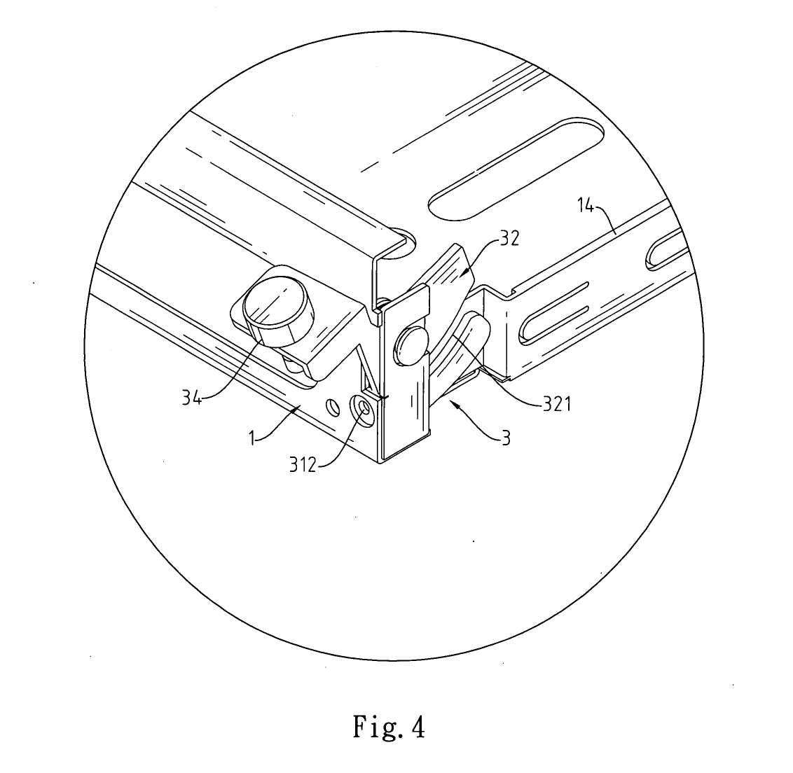

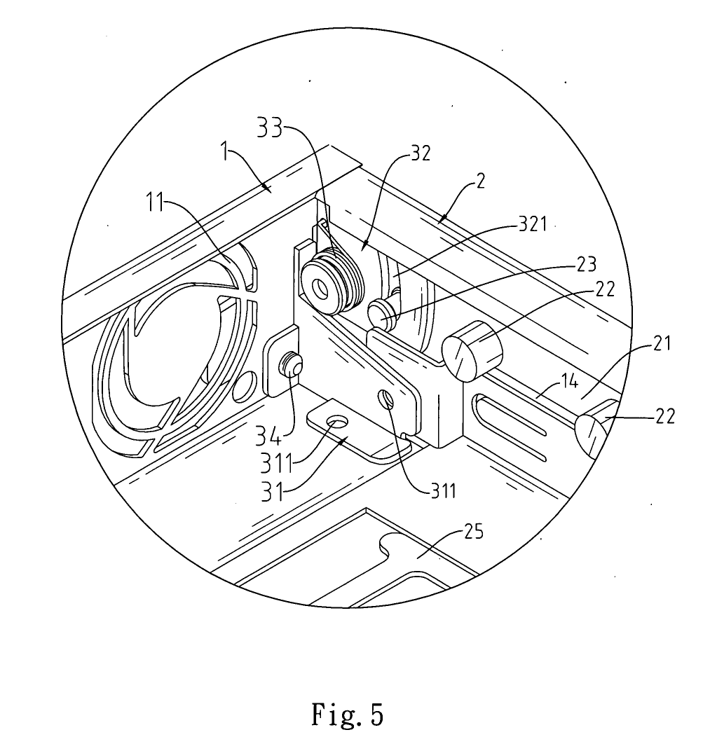

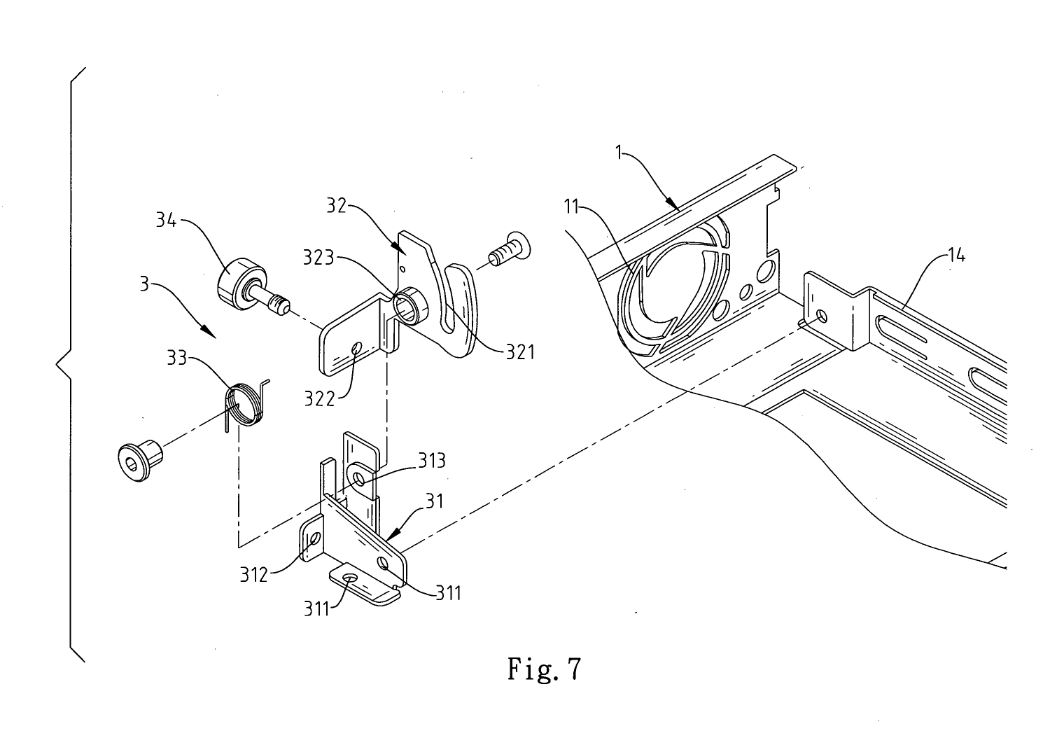

Referring to FIGS. 4 through 8, the movable fasteners 3 are provided at the first bracket 1 for locking the first bracket 1 to the second bracket 2. Each movable fastener 3 comprises a mounting plate 31, a guide plate 32, a return spring 33, and a hand screw 34. The mounting plate 31 is fixedly fastened to one end of one sliding rail 14, having at least one, for example, two mounting holes 311, a locating hole 312, and a pivot hole 313. The first mounting holes 311 are affixed to the first bracket 1. The guide plate 32 and the return spring 33 are pivotally coupled to the pivot hole 313 of the mounting plate 31. The return spring 33 has one end stopped against one side of the mounting plate 31, and the other end connected to the guide plate 32. The guide plate 32 has an elongated guide notch 321, a locating hole 322, and a pivot hole 323. The pivot hole 323 of the guide plate 32 is pivotally coupled to the pivot hole 313 of the mounting plate 31 so that the guide plate 32 can be turned relative to the mounting plate 31 between a first position and a second position. After connection of the guide plate 32 to the mounting plate 31, the guide notch 321 is disposed corresponding to one retaining rod 23 of the second bracket 2. When the guide plate 32 is turned to the second position, the guide notch 321 is forced into engagement with one retaining rod 23 of the second bracket 2, securing the second bracket 2 to the first bracket 1, and at the same time the locating hole 322 is aimed at the locating hole 312 so that the hand screw 34 can be threaded into the locating hole 322 of the guide plate 32 into the locating hole 312 of the mounting plate 31 to lock the guide plate 32 to the mounting plate 31 in the second position.

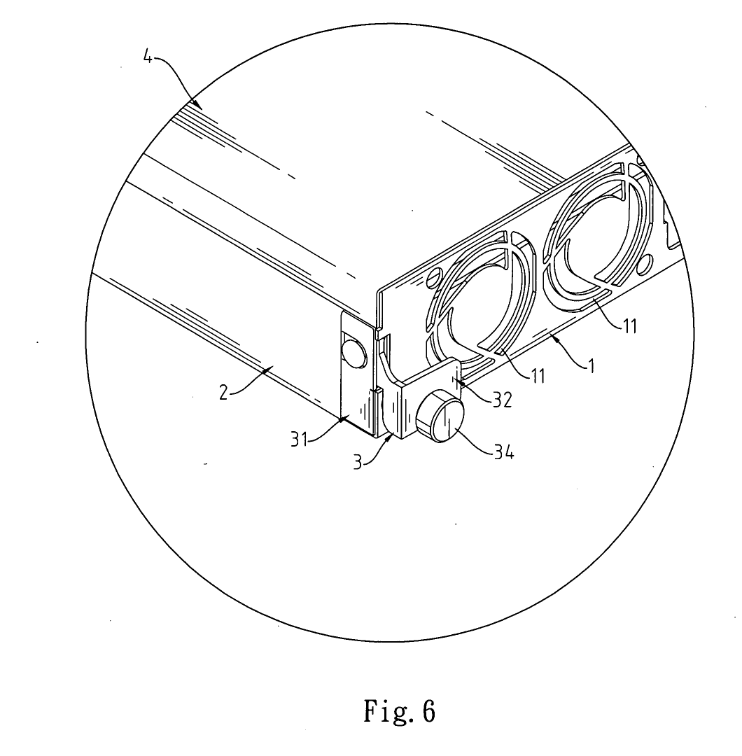

Referring to FIG. 6 and FIG. 1 again, the cover plate 4 is affixed to the two opposite side panels 21 of the second bracket 2 to protect the second bracket 2 and the first bracket 1 in the second bracket 2.

Referring to FIGS. 1 and. 4-8 again, the second bracket 2 is adapted to hold data storage devices 5, and the first bracket 1 is adapted to hold processors 6. When inserting the sliding rails 14 of the first bracket 1 into the inside of the second bracket 1 between the two opposite side panels 21 of the second bracket 2, the guide plates 32 of the movable fasteners 3 are respectively disposed in the first position with the respective guide notches 321 respectively aimed at the retaining rods 23 of the second bracket 2. After insertion of the first bracket 1 into the second bracket 2 to a predetermined depth, the guide notches 321 of the movable fasteners 3 are respectively forced into engagement with the retaining rods 23 of the second bracket 2. Thereafter, the guide plates 32 of the movable fasteners 3 are turned from the first position to the second position to aim the locating holes 322 of the guide plates 32 at the locating holes 312 of the associating mounting plates 31, and then the respective hand screws 34 are respectively threaded into the locating holes 322 of the respective guide plates 32 into the locating holes 312 of the respective mounting plates 31 to lock the first bracket 1 and the second bracket 2.

When replacing the first bracket 1 or the second bracket 2, loosen the hand screws 34 from the associating locating holes 312 for enabling the respective retain springs 33 to return the associating guide plates 32 to the first position, and then pull the first bracket 1 outwards to separate the first bracket 1 from the second bracket 2.

According to the present preferred embodiment, there are two movable fasteners 3 respectively provided at the outer ends of the sliding rails 14 of the first bracket 1. Therefore, the movable fasteners 3 are symmetrical.

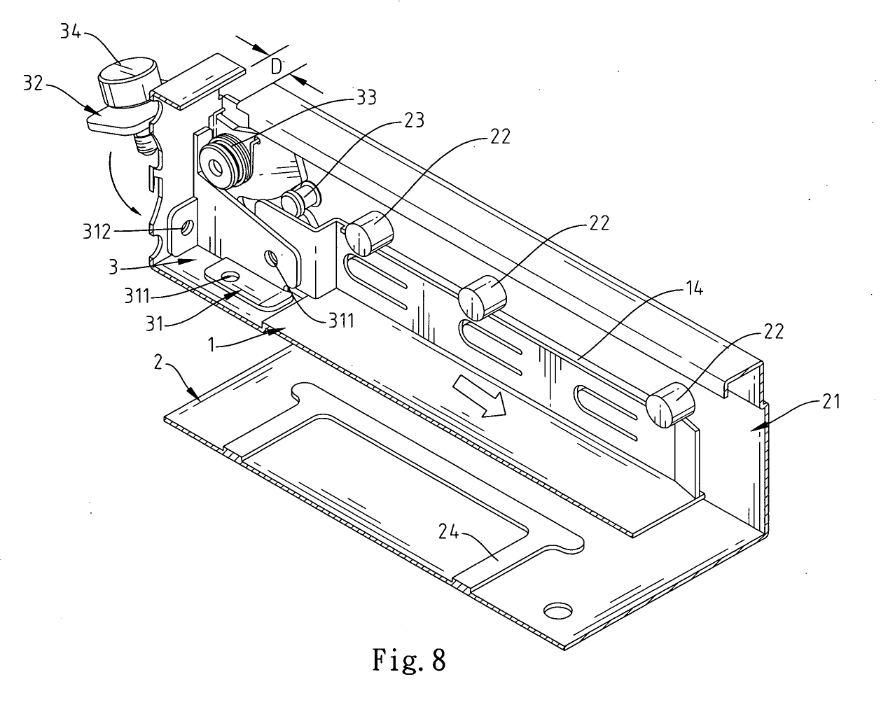

Referring to FIG. 8 again, when the front end of the guide notch 321 of each movable fastener 3 is attached to the associating retaining rod 23, the first bracket 1 and the second bracket 2 are still kept apart at a distance. When the retaining rod 23 is stopped at the bottom end of the associating guide notch 321, the first bracket 1 and the second bracket 2 are kept closely attached to each other.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A modularized server housing comprising:
a first bracket, said first bracket comprising two sliding rails disposed at two opposite lateral sides thereof;
a second bracket for receiving said first bracket, said second bracket comprising two upright side panels disposed at two opposite lateral sides thereof for guiding said sliding rails into the inside of said second bracket, said upright side panels each having a retaining rod disposed near a front side of said second bracket; and
a plurality of movable fasteners respectively provided at said first bracket for fastening to the retaining rods of said upright side panels to lock said first bracket to said second bracket.

2. The modularized server housing as claimed in claim 1, wherein said first bracket has a plurality of fan holes on a front side thereof.

3. The modularized server housing as claimed in claim 1, wherein said first bracket comprises a sliding groove on a horizontal bottom wall thereof for guiding movement of said first bracket in and out of said second bracket, and a through hole at one end of said sliding groove for engagement with a part of said second bracket.

4. The modularized server housing as claimed in claim 3, wherein said second bracket comprises a retaining member forwardly protruding from a front side thereof corresponding to the sliding groove of said first bracket for guiding movement of said first bracket relative to said second bracket and for engaging the through hole at one end of said sliding groove.

5. The modularized server housing as claimed in claim 1, wherein said upright side panels of said second bracket each comprise a plurality of guide rods for guiding movement of said first bracket in and out of said second bracket.

6. The modularized server housing as claimed in claim 1, wherein said second bracket has a plurality of reinforcing ribs protruded from a bottom surface thereof to reinforce the strength of said second bracket.

7. The modularized server housing as claimed in claim 1, further comprising a cover plate affixed to the upright side panels of said second bracket to protect said second bracket and said first bracket.

8. The modularized server housing as claimed in claim 1, wherein said movable fasteners each comprise:
a mounting plate affixed to one end of one of said sliding rails;
a guide plate pivoted to said mounting plate, said guide plate comprising a guide notch for coupling to one retaining rod of said second bracket and a locating hole;
a return spring coupled between said mounting plate and said guide plate; and
a hand screw mounted on said guide plate for fastening to said mounting plate to lock said guide plate to said mounting plate after engagement of said guide notch with the associating retaining rod of said second bracket.

9. The modularized server housing as claimed in claim 8, wherein said mounting plate comprises at least one mounting hole affixed to said first bracket, a locating hole for receiving the associating hand screw, and a pivot hole; said guide plate comprises a pivot hole pivoted to the pivot hole of said mounting plate; said return spring is pivotally coupled between the pivot hole of said mounting plate and the pivot hole of said guide plate, having one end stopped against one side of said mounting plate and an opposite end connected to said guide plate.
